(19) United States
(12) Patent Application Publication
(10) Pub. No.: US 2018/0295757 A1
(43) Pub. Date: Oct. 11, 2018

(54) HOUSING FOR ENCLOSING AT LEAST ONE ELECTRICAL COMPONENT OF A MOTOR VEHICLE, AND METHOD OF MOUNTING A HOUSING

(71) Applicant: AUTOLIV DEVELOPMENT AB, VARGARDA (SE)

(72) Inventors: ROGER WIGREN, LJUNGSBRO (SE); MELIH GUNES, WIXOM, MI (US)

(73) Assignee: AUTOLIV DEVELOPMENT AB, VARGARDA (SE)

(21) Appl. No.: 15/757,172

(22) PCT Filed: Aug. 31, 2016
(86) PCT No.: PCT/EP2016/070492

§ 371 Date: Mar. 2, 2018

(30) Foreign Application Priority Data
Sep. 3, 2015 (EP) 15183729.1

(51) Int. Cl. H05K 9/00; H05K 5/00; H05K 5/02; H05K 5/04; H04N 5/225; B60R 11/04

(52) U.S. Cl. CPC H05K 9/0049; H05K 5/0004; B60R 11/04; H05K 5/04; H04N 5/2252; H05K 5/0217

(57) ABSTRACT

A housing (10) for enclosing at least one electronic component of a motor vehicle having at least a first housing part (20) with a first circumferential connection surface (21) and a second housing part (30) with a second circumferential connection surface (31). The housing parts (20, 30) connect to each other along a connection direction such that the circumferential connection surfaces (21, 31) lie face to face to each other in the connected state. At least one of the housing parts (20) has a plurality of cutting elements (22) protruding from the corresponding circumferential connection surface (21). At least a part of the cutting elements (22) have an oversize with respect to the other circumferential connection surface (31), such that the cutting elements (22) cut into the other circumferential connection surface (31) during connection of the housing parts (20, 30).

### CROSS-REFERENCE TO RELATED APPLICATIONS

This application is a 35 U.S.C. § 371 national phase application of PCT International Application No. PCT/EP2016/070492, filed Aug. 31, 2016, which claims the benefit of priority under 35 U.S.C. § 119 to European Patent Application No. 15183729.1, filed Sep. 3, 2015, the contents of which are incorporated herein by reference in their entirety.

### FIELD OF THE INVENTION

The invention relates to a housing for enclosing at least one electrical component of a motor vehicle, including at least a first housing part with a first circumferential connection surface and a second housing part with a second circumferential connection surface. The housing parts are designed to be connected to each other along a connection direction such that the first circumferential connection surface and the second circumferential connection surfaces lie face to face to each other in the connected state. The invention also relates to a method of mounting such a housing.

### BACKGROUND

Camera devices of a vision system for a motor vehicle are usually protected by a metal housing. The housing should not only give a protection against mechanical stress or damage, but also shield against electromagnetic waves. However, when the housing is put together by two or more housing parts, the Faraday cage formed by the housing parts may have gaps at the connection surfaces of the housing parts. In such case electromagnetic waves could penetrate into the housing and cause a malfunction of the electrical components inside the housing. Also, electromagnetic waves originating from the electrical components inside the housing could penetrate to the exterior of the housing and cause malfunctions of other electrical devices in the motor vehicle.

The problem underlying the present invention is to provide a fail-safe Faraday cage giving a better protection and shielding against electromagnetic waves for electrical components inside and outside the housing.

### SUMMARY AND INTRODUCTORY DESCRIPTION

The invention solves the above-mentioned object with the features of the embodiments described herein. Cooperating first and second housing parts each have circumferential connection surfaces and the housing parts are designed to be connected to each other along the connection surfaces such that the circumferential connection surfaces lie face to face to each other in the connected state of the housing parts. According to the invention, at least one of the housing parts forms a plurality of cutting elements protruding from the corresponding circumferential connection surface. At least a part of the cutting elements has an oversize with respect to the other circumferential connection surface, such that the cutting elements cut into the other circumferential connection surface during connection of the housing parts. The cutting elements are distributed over the circumference of the circumferential connection surface. The cutting elements of the invention generate metal to metal contact points distributed over the circumference of the circumferential connection surface, and thus close the Faraday cage formed by the housing parts, bridging the gap between the first and the second housing part so that no electromagnetic waves can penetrate into or out from the housing.

In order to achieve a good fit between the first and the second housing part, the circumferential connection surfaces of the first and the second housing parts are advantageously oriented parallel to the connection direction, so that the connection can be achieved by a simple translational motion.

Preferably the cutting elements have a longitudinal axis oriented parallel to the connection surfaces of the first and the second housing part. In this case there is no lateral force pushing one of the housing parts away from the connection direction and a fixing of both housing parts by a simple translational motion is possible.

Preferably the cutting elements are tapering in the connection direction in a view onto the corresponding circumferential surface. Therefore a force during the connecting process increases when the first and the second housing part are connected, so that the connecting process can be reliably controlled.

Preferably the cutting elements are arranged with a distance to a front edge of the corresponding housing part which comes first into contact with the other housing part during the connection of the housing parts. As a result, the edge of the one housing part can be used as a centering feature during connecting both housing parts, which eases the connecting process.

Preferably a front part of the cutting elements has an undersize with respect to the other circumferential connection surface. Therefore the front part of the cutting elements will fit easily in the other housing part. The connection will be strengthened when a back part of the cutting elements on one of the housing parts provide an advantageous press-fit with the circumferential connection surface of the other housing part.

In a preferred embodiment of the invention at least one of the housing parts has a planar surface so that the cutting elements on one of the housing parts can scratch or cut into the planar surface of the other housing part.

Preferably the housing parts are made of aluminum. Aluminum has a comparably light weight and a high electrical conductivity and is therefore a preferred material for the housing parts. More preferably, the housing parts are made of die-cast aluminum as a die cast process allows to build a complex geometry on the housing parts including the circumferential connection surfaces as well as the cutting elements. The manufacturing tolerances of a die-cast aluminum are sufficient to reach the tolerances for components such as housings.

A preferred tapering of the cutting elements avoids high forces in the first state of the connection process. The oversize of the rear part of the cutting elements with respect to the circumferential connection surface of the second housing part allows a safe and reliable press-fitting when the rear part of the cutting elements cut into the surface of the other housing part. The surface of the cutting elements should have a relatively small angle with the longitudinal axis through the cutting elements to avoid high forces when the housing parts are connected. To build up a fail-safe Faraday cage, the length of the cutting elements is preferable between 2 mm and 15 mm, more preferable between 5 mm and 10 mm.

In a preferred embodiment of the invention, the cutting elements are spaced from each other by a distance of not more than 50 mm, preferably not more than 35 mm, more preferably not more than 20 mm. A highly efficient Faraday cage protects against high-frequency electromagnetic fields, because on the surface of the cage eddy currents are induced which counteract the external field. The shielding effect is in this case characterized by finite shielding attenuation and penetration into the housing so that the electronic components inside the housing are protected. Smaller distances between the cutting elements are generally preferred as the penetration gets smaller and the shielding effect more reliable.

Preferably the cuttings elements have a maximum thickness which is larger than a gap between the circumferential connection surfaces in the connected stated of the housing parts. Therefore the cuttings elements fit into the other housing part with a press-fitting, scratching or cutting action into the circumferential connection surface, thus penetrating any passivation layer of an aluminum housing part and making good electrically conductive contact. Herein, the thickness of the cutting elements is measured in a non-connected state of the housing parts.

According to a preferred embodiment of the invention, the cutting elements are knife-shaped, needle-shaped, spike-shaped or pyramid-shaped. Such shapes are preferable to cut into the other housing part, penetrate a passivation layer and build up a Faraday cage.

The housing parts may be metal housing parts, i.e. made of metal, or basically non-metal housing parts, like plastic housing parts, having a conductive coating, like metal coating, or a conductive layer, like a metal layer. Generally, the housing parts are designed such that they form a Faraday cage when being connected to each other, thus being housing shielding parts. The cutting elements and/or the other circumferential connection surface are preferably made of metal, or have a metal surface coating.

### BRIEF DESCRIPTION OF THE DRAWINGS

In the following the invention shall be illustrated on the basis of preferred embodiments with reference to the accompanying drawings, wherein:

FIG. 1 shows a schematic drawing of a metal housing according to the invention, wherein the housing parts are shown in a non-connected state;

FIG. 2 shows a schematic drawing of a metal housing according to the invention, wherein the housing parts are shown in a connected state;

FIG. 3 shows a perspective view on a first housing part according to the invention;

FIG. 4A shows a view on the rear side of the first housing part of FIG. 3, and FIG. 4B is a cut-away detail drawing from FIG. 4A; and

FIG. 5A shows a detailed side view of a cutting element in a cross section through the first housing part of FIGS. 3, 4A and 4B, and FIG. 5B is a cut-away detail drawing from FIG. 5A.

### DETAILED DESCRIPTION

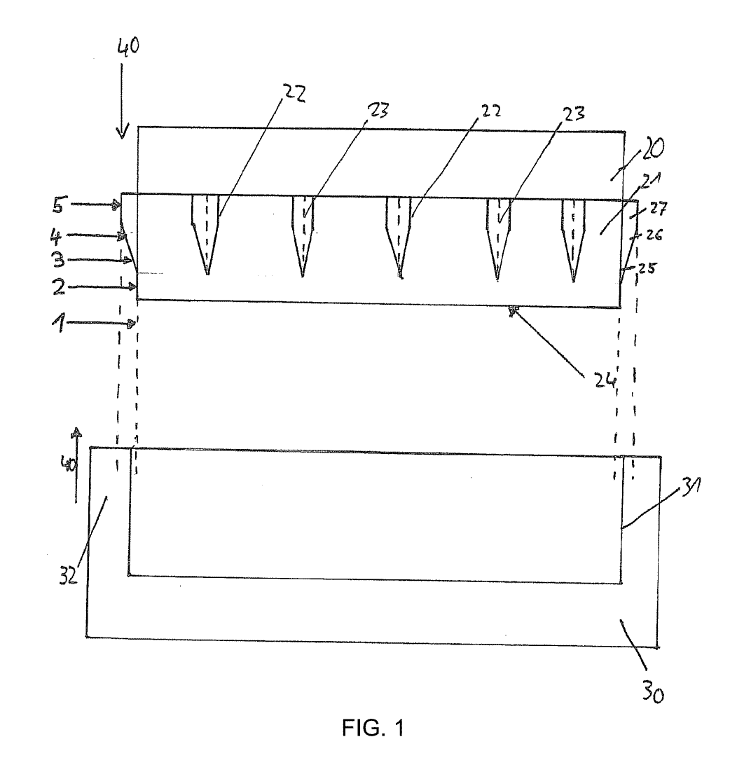

FIG. 1 shows a housing 10 for enclosing at least one electronic component of a motor vehicle, such as one or more camera modules not shown in the figures. The housing 10 includes a first metal housing part 20 with a first circumferential connection surface 21 and a second metal housing part 30 with a second circumferential connection surface 31. The circumferential connection surfaces 21, 31 of the metal housing parts 20, 30 are planar surfaces. The first metal housing part 20 and the second metal housing part 30 are designed to be connected to each other along a connection direction 40 such that the circumferential connection surfaces 21, 31 lie face to face to each other in a connected state of those metal housing parts 20, 30.

The first metal housing part 20 includes a plurality of cutting elements 22 protruding from the planar surface of the circumferential connection surface 21. The cutting elements 22 are arranged with a distance to a front edge 24 of the first metal housing part 20. The cutting elements 22 have a length of 2 mm to 15 mm, preferably between 5 mm to 10 mm. Each cutting element has a front part 25, a rear part 26 and may have a straight part 27. The front part 25 has an undersize with respect to the circumferential connection surface 31 of the second metal housing part 30 (for forming a clearance fit) and the rear part 26 has an oversize with respect to the circumferential connection surface 31 of the second metal housing part 30 (for forming an interference fit). The straight part 27 can also have an oversize with respect to the circumferential connection surface 31.

The cutting elements 22 are equally spaced along the circumferential connection surfaces 21, 31, preferably by a distance of not more than 50 mm, preferably not more than 35 mm, more preferably not more than 20 mm relative to each other. The cutting elements 22 have a spike-shape, but may also have a knife-shape, a needle-shape or a pyramid-shape, for example.

The connection direction 40 is shown with arrows alongside the both metal housing parts 20, 30 in FIG. 1. The numbers 1 to 5 relate to different states of the connection process in which first part 20 is inserted into and assembled with second housing part 30, starting from a non-connected state 1 (the parts are separated) to a fully connected state 5 (final assembly). In state 2, the front edge 24 of the first metal housing 20 dives into the second metal housing part 30 and there is no forced contact, as the front edge 24 of the first metal housing part 20 has an undersize with respect to a collar 32 of the second metal housing part 30. In state 3, the front parts 25 of the cutting elements 22 dive into (interference with) the collar 32 of the second metal housing part 30 until the cutting elements 22 get in touch with the connection surface 31 of the second metal housing part 30. In state 4, the rear part 26 of the cutting elements 22 cut into the connection surface 31 of second metal housing part 30. Following state 4, the straight part 27 of the cutting elements 27 come into press-fit contact with the connection surface 31 until a fully connected state 5 is reached.

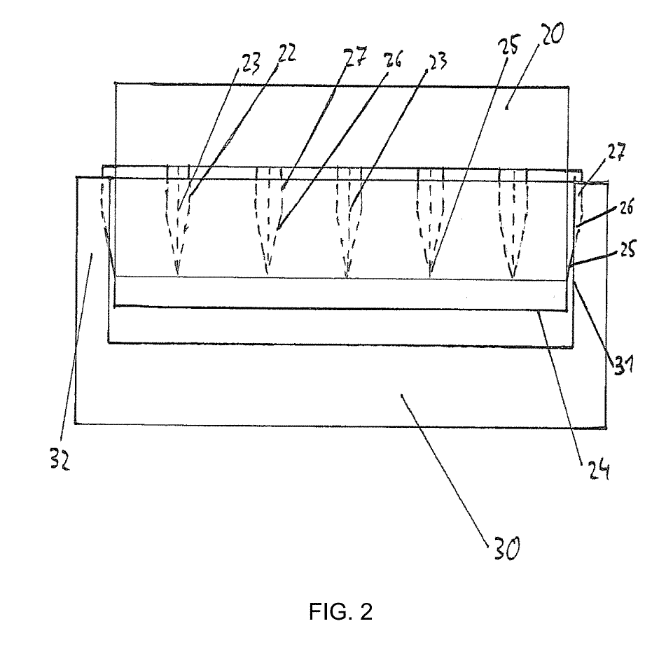

FIG. 2 shows the housing 10 with the first metal housing part 20 and the second metal housing part 30 in a fully connected state corresponding to state 5 in FIG. 1, wherein at least the rear parts 26 and, if present, the straight parts 27 of the cutting elements 22 have an oversize with respect to the circumferential connection surface 31 of the second housing part 30.

The circumferential connection surfaces 21, 31 are orientated generally parallel to the connection direction 40 of the metal housing parts 20, 30. The first metal housing part 20 and the second metal housing part 30 provide a press fitting along the cutting elements 22 when both metal housing parts 20, 30 are connected to each other in state 5. The metal housing parts 20, 30 thus form a Faraday cage along the circumferential connection surfaces 21, 31, such that the cutting elements 22 close a gap between the two metal housing parts 20, 30. A maximum thickness of the cutting elements 22 is larger than a gap between the circumferential connecting surfaces 21, 31 in the connected state of the first metal housing part 20 and the second metal housing part 30.

The metal housing parts 20, 30 not only provide mechanical protection but also shielding against electromagnetic waves to electronic components inside and outside the housing 10. The cutting elements 22 have a longitudinal axis 23 which is orientated parallel to the connection direction of the two housing parts 20, 30. The cutting elements 22 are tapering in the connection direction in a view onto the corresponding circumferential connection surface 21, and in a view along the corresponding circumferential connection surface 21.

The metal housing parts 20, 30 are made of an electrical conductive material such as aluminum, preferable die-cast aluminum, and formed in a casting process. The metal housing parts 20, 30 and the cutting elements 22 are advantageously made from the same material.

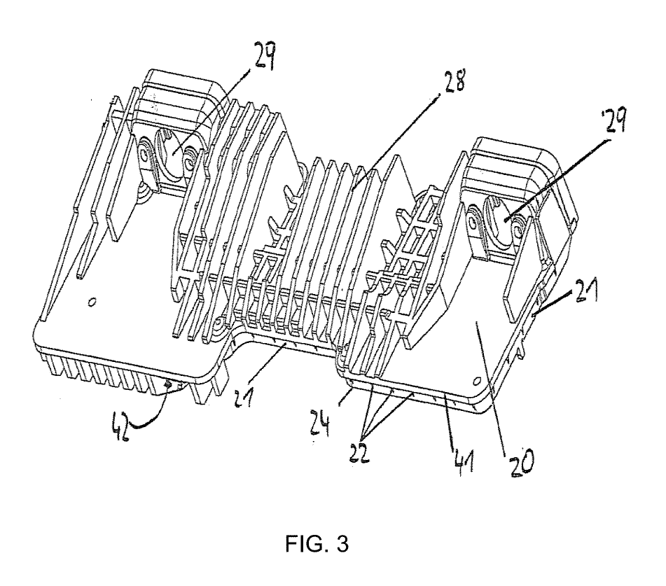

FIGS. 3 to 5 show different views of a practical embodiment of a first housing part 20. The first metal housing part 20 has a pair of openings 29 for receiving a camera module, and ribs 28, such as cooling ribs or reinforcing ribs. The first metal housing part 20 has a circumferential connection surface 21 with a planar base. A plurality of cutting elements 22 is distributed over the circumference of the circumferential connection surface 21 and protrudes from the planar base. The cutting elements 22 are equidistantly spaced over the circumference of the connection surface 21, with a distance of 8 to 10 mm between one cutting element 22 and an adjacent cutting element 22. The first housing part 20 has a preferably circumferential flange 41, which can be used as a stop surface 42 when the first housing part 20 and the second housing part 30 are connected.

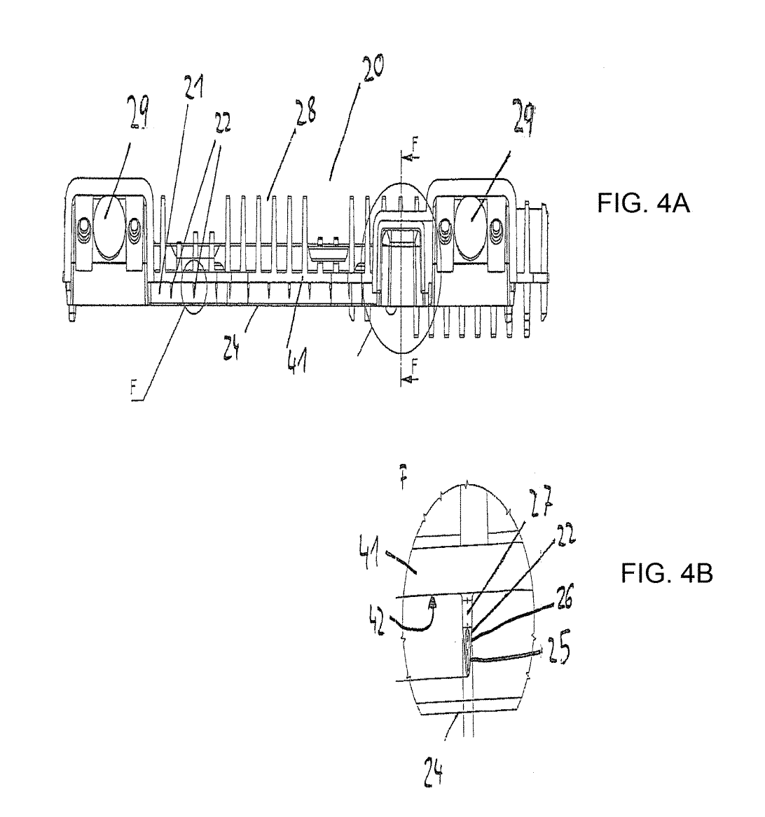

The detail F of FIG. 4B shows an enlarged view onto one of the cutting elements 22. The cutting element 22 is tapering and has a front part 25 with is smaller and thinner than a rear part 26. The detail F also shows an enlarge view of the flange 41 and the stop surface 42. Therefore the level of the fully connected state 5 can also lie on a level, where a front edge of the second housing part 30 is in contact with the stop surface 42 of the flange 41 of the first housing part 20.

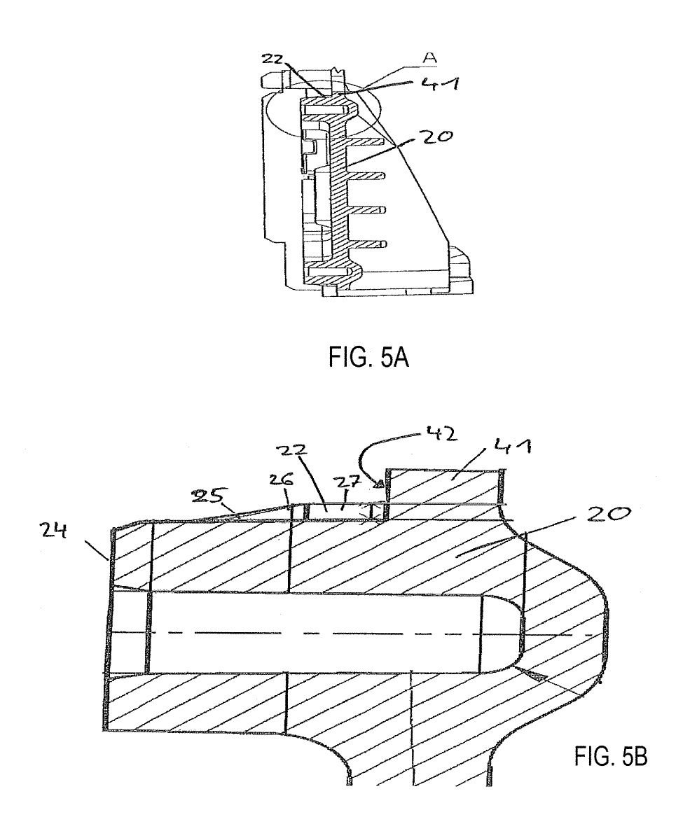

FIG. 5B shows an enlarged cross sectional view of the first metal housing part 20. As shown in FIG. 5B, the cutting element 22 is distanced from the front edge 24 of the first metal housing part 20 and has a front part 25, a rear part 26 and a straight part 27. The straight part 27 extends to the prefer-ably circumferential flange 41, so the stop surface 42 can build a stop for the front edge of the second housing part when the two housing parts 20, 30 are connected in the connection direction 40 in state 5.

When the housing 10 is mounted, the first metal housing part 10 and the second metal housing part 20 are connected along the connection direction 40, the circumferential connection surfaces 21, 31 being oriented parallel to the connection direction. When the front edge 24 of the first housing part 20 dives into a collar 9 of the second housing part 30 there is a gap between those two housing parts 20, 30. The front parts 25 of the cutting elements 22 on the circumferential connection surface 21 of the first metal housing part 20 have an undersize with respect to the other circumferential connection surface 31 of the second metal housing part 30. Due to the tapered shape of the cutting elements 22 and the fact that the cutting elements 22 have a thickness that is larger than the gap between the two metal housing parts 20, 30 in a connected state, the rear part 26 of each cutting element 22 scratches or cuts into the other circumferential connection surface 31. The cutting elements 22 thus penetrate any passivation layer on the aluminum of the second metal housing part 30. Furthermore, when the two metal housing parts 20, 30 are connected in the fully connected state, the straight parts 27 of the cutting elements 22 are in press-fit contact with the connection surface 31 of the second metal housing part 30 and thus form a tight connection of the two metal housing parts 20, 30. The stop surface 42 can assist in a connection process so that the fully connected state 5 is not only defined by a force for the press fitting connection but also by a defined stop.

Generally it is possible to have cutting elements 22 not only on one housing part, here the first metal housing part 20, but on both housing parts, here also on the second metal housing part 30. In an embodiment not shown, the cutting elements 22 can be distributed alternating on both metal housing parts 20, 30 so that the cutting elements 22 on the first metal housing part cut into the planar part of the second circumferential connection surface 31 of the second metal housing part and the cutting elements 22 on the second metal housing part 30 cut into the planar part of the first circumferential connection surface 21 of the first metal housing part 20.

While the above description constitutes the preferred embodiment of the present invention, it will be appreciated that the invention is susceptible to modification, variation and change without departing from the proper scope and fair meaning of the accompanying claims.

1. A housing for enclosing at least one electronic component of a motor vehicle, comprising, at least a first housing part with a first circumferential connection surface and a second housing part with a second circumferential connection surface, wherein the first and second housing parts are configured to be connected to each other along a connection direction such that the first and second circumferential connection surfaces lie face to face to each other in a connected state of the first and second housing parts, the first housing part comprises a plurality of cutting elements protruding from the first circumferential connection surface, wherein at least a part of the cutting elements have an oversize with respect to the second circumferential connection surface, such that said the cutting elements cut into the second circumferential connection surface during connection of the first and second housing parts, wherein the plurality of cutting elements are distributed over the circumference of the first circumferential connection surfaces.

2. The housing according to claim 1, further comprising, the first and second circumferential connection surfaces are oriented parallel to the connection direction.

3. The housing according to claim 1, further comprising, the cutting elements have a longitudinal axis oriented parallel to the connection direction.

4. The housing as claimed in claim 1, further comprising, the cutting elements are tapering in the connection direction in a view onto the corresponding first circumferential connection surface.

5. The housing as claimed in claim 1, further comprising, the cutting elements are arranged with a distance to a front edge of the first housing part which comes first into contact with the second housing part during the connection of the housing parts.

6. The housing as claimed in claim 1, further comprising, a front part of the cutting elements has an undersize with respect to the second circumferential connection surface.

7. The housing according to claim 1, further comprising, the circumferential connection surface is a planar surface of one of the housing parts.

8. The housing as claimed in claim 1, further comprising, the first and second housing parts are made of aluminum, or die-cast aluminum.

9. The housing according to claim 1, further comprising, the cutting elements have a length between 2 mm to 20 mm.

10. The housing according to claim 1, further comprising, the cutting elements are equally spaced along the first circumferential connection surface.

11. The housing according to claim 1, further comprising, the cutting elements are spaced from each other by a distance of not more than 50 mm.

12. The housing according to claim 1, further comprising, the cutting elements have a maximum thickness which is larger than a gap between the first and second circumferential connection surfaces in the connected state of the housing parts.

13. The housing according to claim 1, further comprising, the cutting elements are any one of knife-shaped, spike-shaped, needle-shaped or pyramid-shaped.

14. A method of mounting a housing to enclose at least one electronic component of a motor vehicle comprising providing at least a first housing part with a first circumferential connection surface and a second housing part with a second circumferential connection surface, comprising connecting the housing parts such that the circumferential connection surfaces are contacting each other face to face in a connected state of the first and second housing parts, wherein the first housing part comprises a plurality of cutting elements which scratch into the surface of the second circumferential connection surface of the second housing part during connection.
